(19) United States
(12) Patent Application Publication
(10) Pub. No.: US 2018/0138752 A1
(43) Pub. Date: May 17, 2018

(54) LONG DISTANCE POSITIONING GUIDE FOR WIRELESS POWER

(71) Applicant: Integrated Device Technology, Inc., San Jose, CA (US)

(72) Inventors: David WILSON, Soquel, CA (US); Christopher STEPHENS, San Jose, CA (US)

(21) Appl. No.: 15/815,315

(22) Filed: Nov. 16, 2017

Related U.S. Application Data
(60) Provisional application No. 62/423,428, filed on Nov. 17, 2016.

(51) Int. Cl. H02J 50/12; G01R 33/022

(52) U.S. Cl. CPC H02J 50/12; G01R 33/022

(57) ABSTRACT

A wireless power receiver is presented that allows for positioning of the receiver with respect to a transmitter coil. The receiver can base alignment information on the wireless power received from the transmit coil. In some embodiments, a secondary detector such as a beacon can be used to provide a direction towards alignment. The power receiver may include a receiver coil, a power detector configured to determine a power level received by the receiver coil, and a processor coupled to receive the power level from the power detector and provide an indication of the power level.

### TECHNICAL FIELD

Embodiments of the present invention are related to wireless power systems and, specifically, to positioning wireless receivers in relations to wireless transmitters.

### DISCUSSION OF RELATED ART

Mobile devices, for example smart phones and tablets, are increasingly using wireless power charging systems. Typically, a wireless power charging system includes a transmitter coil that is driven to produce a time-varying magnetic field and a receiver coil that is positioned relative to the transmitter coil to receive the power transmitted in the time-varying magnetic field. One of the technical challenges is, then, to position the receiver coil relative to the transmitter coil in order to optimize the transmission of power from the transmitter coil to the receiver coil.

Therefore, there is a need to develop better positioning technology that allows for positioning of the receiver coil relative to the transmitter coil.

### SUMMARY

In accordance with some aspects, a wireless power receiver that provides for alignment with a transmitter is presented. In some embodiments, a wireless power receiver can include a receiver coil; a power detector configured to determine a magnetic field strength; and a processor coupled to receive the power level from the power detector and configured to provide an indication of the power level, wherein an alignment between the receiver coil and a corresponding transmitter coil can be accomplished based at least in part on the power level.

In some embodiments, the receiver can include a user interface that includes a power level meter coupled to receive the power level from the processor wherein a user can move the wireless power receiver according to the power level indicated on the power level meter to achieve alignment. In some embodiments, a motion detector coupled to the processor, wherein the processor is configured to determine a direction to move the power receiver based on a gradient of the power level received with position. In some embodiments a secondary detector can be used to provide alignment information.

In some embodiments, a method of aligning a receiver with a transmitter can include receiving a power signal indicating a received wireless power from the transmitter; and determining an alignment direction between the receiver and the transmitter based on the power signal.

In some embodiments, a method of aligning a receiver with a transmitter includes receiving a secondary signal from a secondary detector; and determining a direction towards alignment based from the secondary signal.

These and other embodiments are further discussed below with respect to the following figures.

### BRIEF DESCRIPTION OF THE DRAWINGS

FIG. 1 illustrates a wireless power transmission system.

FIG. 2 illustrates a receiver of a wireless power transmission system positioning against a wireless power transmitter.

FIGS. 3A and 3B illustrate example magnetic field strength profiles as a function of distance from the center of the transmitter coil.

FIGS. 4A and 4B illustrate example embodiments of a receiver device.

FIG. 4C illustrates algorithms for positioning the receiver device illustrated in FIGS. 4A and 4B.

FIGS. 5A, 5B, and 5C illustrate an example system that uses secondary positioning systems.

FIG. 5D illustrates algorithms for positioning the receiver device illustrated in FIG. 5C.

### DETAILED DESCRIPTION

In the following description, specific details are set forth describing some embodiments of the present invention. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure.

This description and the accompanying drawings that illustrate inventive aspects and embodiments should not be taken as limiting—the claims define the protected invention. Various changes may be made without departing from the spirit and scope of this description and the claims. In some instances, well-known structures and techniques have not been shown or described in detail in order not to obscure the invention.

Elements and their associated aspects that are described in detail with reference to one embodiment may, whenever practical, be included in other embodiments in which they are not specifically shown or described. For example, if an element is described in detail with reference to one embodiment and is not described with reference to a second embodiment, the element may nevertheless be claimed as included in the second embodiment.

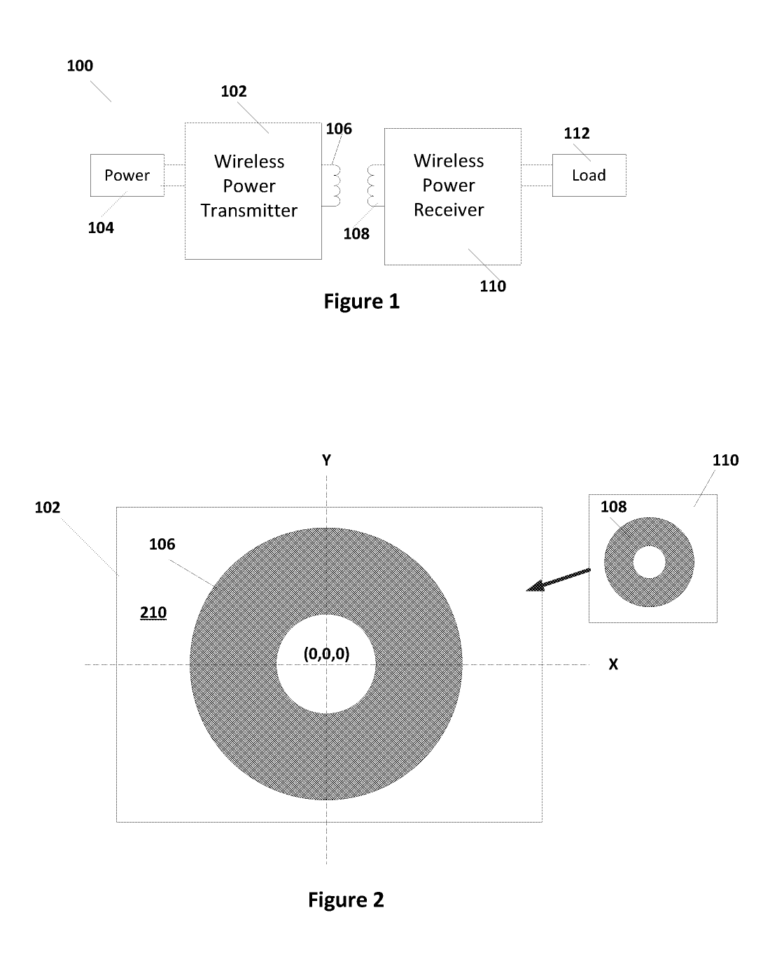

FIG. 1 illustrates a system 100 for wireless transfer of power. As illustrated in FIG. 1, a wireless power transmitter 102 drives a coil 106 to produce a magnetic field. A power supply 104 provides power to wireless power transmitter 102. Power supply 104 can be, for example, a battery based supply or may be powered by alternating current for example 120V at 60 Hz. Wireless power transmitter 102 drives coil 106 at, typically, a range of frequencies according to one of the wireless power standards. Embodiments of the present invention may be used with any of the wireless power standards, or with any wireless power transmission system.

There are multiple standards for wireless transmission of power, including the Alliance for Wireless Power (A4WP) standard and the Wireless Power Consortium standard, the Qi Standard. Under the A4WP standard, for example, up to 50 watts of power can be inductively transmitted to multiple charging devices in the vicinity of coil 106 at a power transmission frequency of around 6.78 MHz. Under the Wireless Power Consortium, the Qi specification, a resonant inductive coupling system is utilized to charge a single device at the resonance frequency of the device. In the Qi standard, coil 108 is placed in close proximity with coil 106 while in the A4WP standard, coil 108 is placed near coil 106 along with other coils that belong to other charging devices. FIG. 1 depicts a generalized wireless power system 100 that operates under any of these standards.

As is further illustrated in FIG. 1, the magnetic field produced by coil 106 induces a current in coil 108, which results in power being received in a receiver 110. Receiver 110 receives the power from coil 108 and provides power to a load 112, which may be a battery charger and/or other components of a mobile device. Receiver 110 typically includes rectification to convert the received AC power to DC power for load 112.

FIG. 2 illustrates an example of a power receiver 110 being positioned relative to a pad 210 that includes transmitter coil 106. FIG. 2 also illustrates an X-Y-Z orthogonal coordinate system, where the X and Y axis are shown and the Z axis is out of the figure orthogonal to both the X and Y axis. As shown in FIG. 2, the coordinates (0,0,0)—X=0, Y=0, Z=0—corresponds to the center of transmission coil 106. The position of device 110 can be described in this coordinate system as (x_{d}, y_{d}, z_{d}).

In some applications, it can be impossible, impractical, or simply undesirable to expect a user, robotic system, or other mechanical system to blindly place receiver device 110 on a precise location on transmit pad 210 in order to achieve optimum power delivery. When the placement uncertainty is greater than about 10 mm, existing methods to guide receiver device 110 are no longer effective. These greater distances can be very large, such as 250 mm. Solutions that move the transmit coil 106 to the location of receiver device 110, provide a very large single coil for transmit coil 106, or where transmit pad 210 supports a multiplicity of coils such that one can be energized under the location of receiver device 110 can be costly.

In some previous examples, a secondary sensing coil can be used to assist with placement guidance over approximately a 10-20 mm range. This method looks for an asymmetry across the sensing coil, and is less useful over large distances or where there is a more uniform magnetic field strength from transmitter coil 106. In another application, the transmitter surface pad 210 can detect a 1 MHz resonance in receiver device 110, which can be used to guide movement of transmitter coil 106 to the optimum location rather than to guide placement of receiver coil 108 in the optimum position.

In accordance with embodiments of the present invention, a lower cost approach is provided by guiding receiver device 110 over a very large distance to reliably place receiver device 110 in an optimum location relative to transmitter coil 106. In some embodiments, this guidance can be provided with indicators on device 110. In some cases, especially when device 110 is a robotic device such as a drone, the guidance can be provided to a propulsion system to direct device 110 to an optimal location.

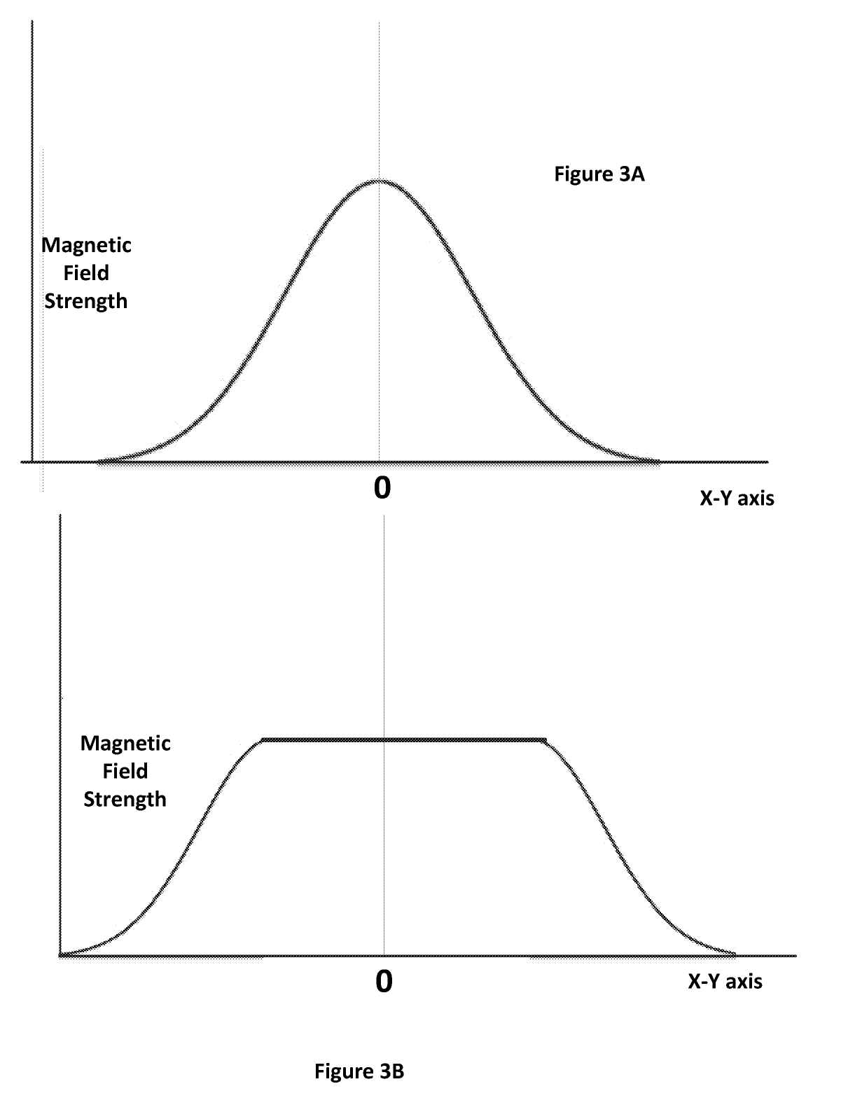

FIG. 3A illustrates a typical graph of magnetic field strength along a line in the X-Y plane passing through X=0, Y=0 at a high Z=H from charging pad 210. As is illustrated, typically an optimal position is over the X=0, Y=0 position on transmitter pad 210. Typically, during charging device 110 can be placed as close to this optimal position as possible and on a surface of transmitter pad 210. Transmitter coil 106 is typically embedded within transmitter pad 210 or mounted to a bottom surface of transmitter pad 210. In the example illustrated in FIG. 3A, the maximum magnetic field strength is at position 0 (representing X=0 and Y=0) and tapers off with distance from position 0 in the X-Y plane. In some cases, the power delivery field could be stepped or sculpted. For example, as shown in FIG. 3B, a step in the field strength indicates that placement is sufficient and the region within the step is suitable for charging.

In general, the magnetic field gradient can be shaped in a variety of ways in order to enhance specific placement methods. Generally, a Gaussian type shape such as that illustrated in FIGS. 3A and 3B can be used. Sculpting of the shape can be achieved by using one or more coils to form the field and/or addition of magnetic materials such as ferrite to further shape the field. As such, the field may be customized in any way.

In some embodiments, receiver device 110 can report to the operator the signal strength of the magnetic field strength or charging power at its present location. With this information, receiver device 110 can be guided and moved precisely to the desired optimum location on transmitter pad 210 based on the gradient of the magnetic field strength as device 110 is moved over transmitter pad 210. Traditionally, an oversize transmitter coil 106 is used and this coil is used to create a very large and uniform charging field so that good performance is possible at any location on transmitter pad 210 over transmit coil 106. In this case, the receiver device 110 can move to maximize the magnetic field strength.

In some embodiments, the magnetic field strength can be relatively contained spatially and the magnetic field strength includes a field strength gradient with distance from the center of transmitter coil 106 (i.e., position 0 in FIGS. 3A and 3B). The operator of receiver device 110 can follow the gradient and thus be guided to the optimum location for power delivery. In some embodiments, receiver device 110 can use the already existing power delivery circuits to detect and navigate the field gradient. In some cases, amplification can also be provided such that the field gradient can be followed from a much greater distance.

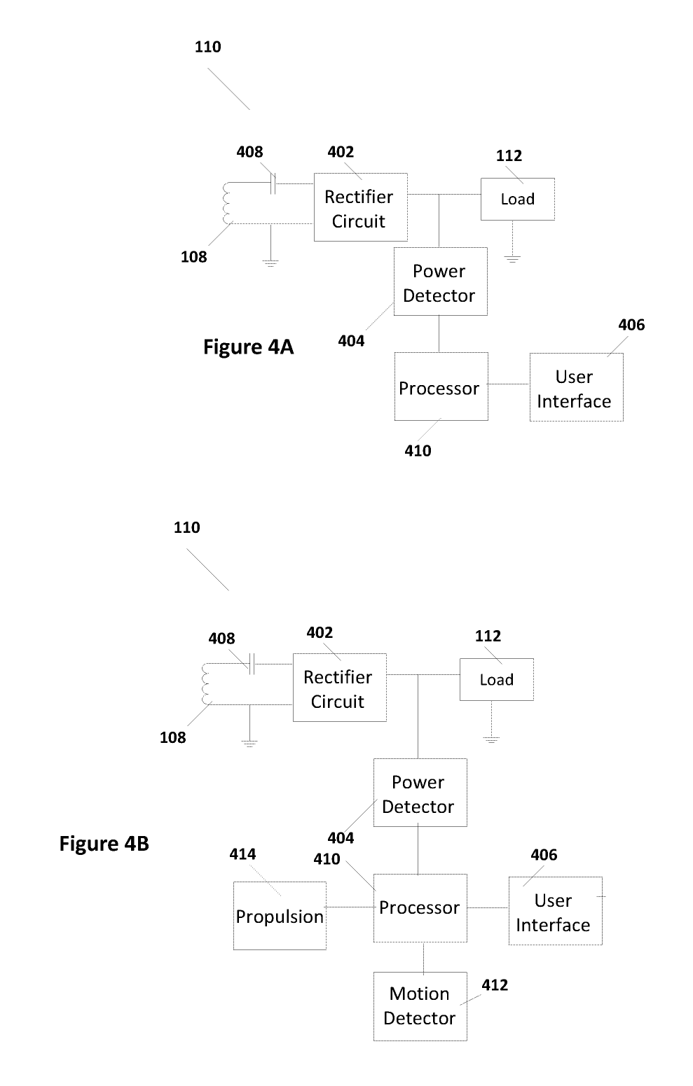

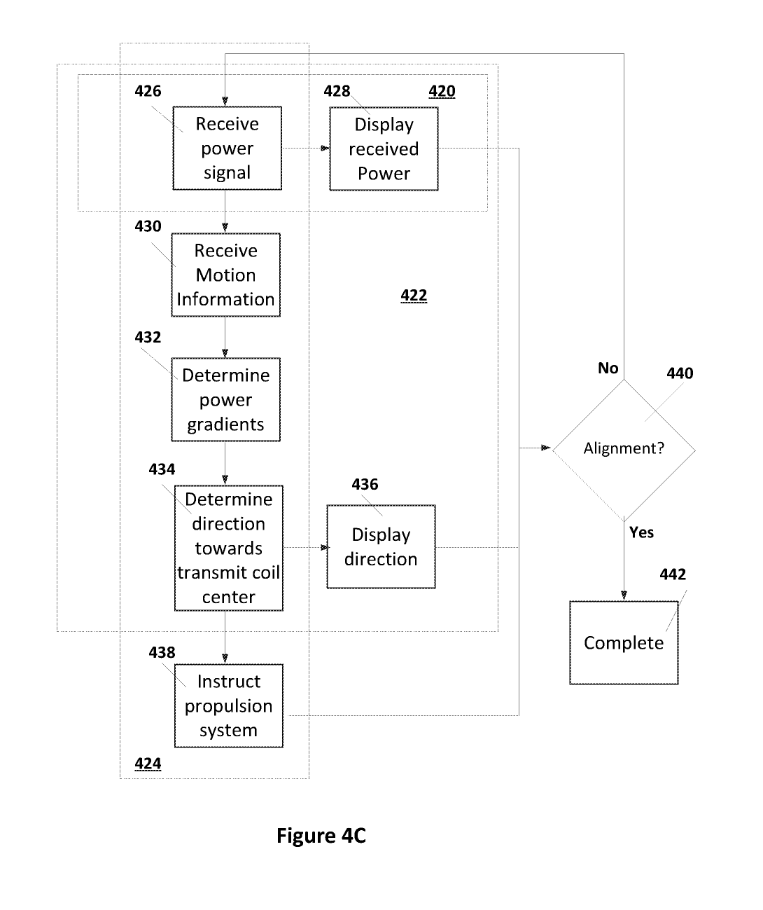

FIG. 4A illustrates an embodiment of device 110 that includes a magnetic field strength indicator for the operator. As illustrated in FIG. 4A, power received at receive coil 108 is provided through capacitor 408 to rectifier circuit 402. Rectifier circuit 402 may include rectification circuitry as well as other circuitry to condition power for use by load 112. In the example illustrated in FIG. 4A, a power detector 404 is provided to determine the power output which is indicative of the power received at receive coil 108. In some embodiments, power detector 404 may monitor power within rectifier circuit 402, for example if rectifier circuit 402 further includes DC power conditioning circuitry. In some embodiments, power detector 404 may be coupled to a separately located magnetic field detection coil positioned on receiver device 110. Power detector 404 may include, for example, A/D converters to provide a digital signal indicative of the received power level to a processor unit 410. Processor unit 410 can provide processing capability configured to determine the power received at receiver coil 108 and provide an indication to a user interface 406 to provide an indicator to a user. As such, processing unit 410 may include volatile and non-volatile memory for holding data and programming instructions as well as one or more processors for executing instructions stored in memory and calculating parameters based on the data from power detector 404. As shown in FIG. 4A, processing unit 410 is coupled to a user interface 406 to provide a power indicator to the user. Although there are numerous ways for indicating a power level to a user, user interface 406 may, for example, display a power gauge to the user indicating the power level or provide an audible signal indicative of the power level.

FIG. 4B illustrates an embodiment where device 110 includes motion sensors 410. Data from motion sensors 412, which can be provided to processing unit 410, can include positional, acceleration, and velocity data that allows processing unit 410 to calculate magnetic field strength gradients and provide further indication in user interface 406 as to a direction in which device 110 should be moved. In such a case, user interface 406 may include a two-dimensional indicator that indicates the direction in the X-Y plane of the largest gradient indicating higher magnetic field strengths. In some cases, as is illustrated in the magnetic field profile of FIG. 3B, user interface 406 can further indicate an absolute field strength and a condition of no magnetic field strength gradient (or a uniform magnetic field strength) as the device 110 is moved in the vicinity of the transmit coil 106.

The example of receiver device 110 illustrated in FIG. 4B can be particular useful if receiver device 110 is a robotic device such as a drone or quadcoptor. FIG. 4B illustrates a propulsion system 414 that may be included in some embodiments. Propulsion system 414 receives instructions regarding the motion of receiver device 110 based on the direction information calculated by processor 410. In that case, the directional information towards higher magnetic field strengths can be used to control the motion of the robotic device in order to position the robotic receiver device 110 (e.g., a drone or other device capable of motion) at an optimal location. In embodiments where a user is physically positioning receiver device 110, propulsion system 414 would not be present.

FIG. 4C illustrates algorithms that can be executed by processor 410 in order to align receiver 110 with transmitter coil 106 to efficiently receive wireless power. Algorithm 420 is applicable to embodiments such as that illustrated in FIG. 4A, for example. As illustrated in Algorithm 420, processor 410 receives a power signal from power detector 404 in step 426 and displays a power level on user interface 406 in step 428. In some embodiments, a user can provide an indication of alignment in step 440 at which time algorithm 420 can exit in step 402.

Embodiments illustrated in FIG. 4B can execute algorithms 422 or 424, depending on whether the embodiment includes propulsion 414 or not. In algorithm 422, which does not include propulsion 414, processor 410 receivers a power signal from power detector 404 in step 426 and displays a power level on user interface 406 in step 428. In step 430, processor 410 receives motion information from motion detector 412. In step 432, processor 412 determines, based on the motion information and the power signal, power gradients. In step 434, processor 410 determines based on the power gradients a direction towards alignment of receiver coil 108 with transmit coil 106. In step 436, the direction towards alignment for the user. Algorithm can then enter alignment test 440 to determine whether or not an alignment of receiver coil 108 with transmit coil 106 has been achieved. If so, then the algorithm may indicate that to the user in complete step 442. Alignment may be considered to be achieved when the gradient is 0 or within some small margin (e.g., within 10% of a maximum power detected) around an area where the gradient is 0.

Algorithm 424 can be used if device 110 includes propulsion 414. In this case, device 110 is handling the positioning of device 110 with respect to transmitter 102 without a user. In that case, there may be no need to display on user interface 406 and therefore algorithm 424 may exclude steps 428 and 436. Instead, step 434 may provide the information to step 438, in which process 410 instructs propulsion 414 to move along the direction towards alignment. Step 440 then determines whether device 110 is aligned with transmitter 102 and, if so, stops device 110 in step 442. As is further illustrated in FIG. 4C, alignment step 440 returns to step 426 to continue a loop until alignment is achieved.

In the algorithms illustrated in FIG. 4C, device 110 should be moved around transmitter 102 in both X and Y directions while motion in a Z direction is minimal. In that case, gradients in the X-Y plane can be calculated (instead of having a gradient only in one direction in the X-Y plane) and a more accurate determination of the direction towards alignment can be made. If device 110 is only moved in a single direction in the X-Y plane, actual alignment may not be achieved.

The embodiments illustrated in FIGS. 4A and 4B and the example algorithms illustrated in FIG. 4C can be used to position device 110 if device 110 is close enough to transmitter pad 210 to detect magnetic field gradients from transmitter coil 106. This distance is limited only by the signal-to-noise ratio, which determines the ability to detect the magnetic field strengths. In some embodiments, detection distances can be large and positioning device 110 precisely on transmitter pad 210 may prove more difficult. However, in some cases, especially in the case of robotic positioning where device 110 first needs to find transmitter pad 210 from a larger distance or distinguish transmitter pad 210 from a series of other transmitter pads, a secondary locating system may be included between transmitter pad 210 and device 110.

In some embodiments, receiver coil 108 is used for detecting the magnetic field. However, in some embodiments it may be advantageous to use a secondary locating system that has a different antenna to detect the magnetic field from receiver coil 108 or from a separate beacon for purposes of navigating device 110 toward receiver coil 108. In some embodiments, a larger coil (larger than receiver coil 108) of very fine wire and possibly not many turns positioned elsewhere on receiver device 110 can be used to detect magnetic fields from receiver coil 108 from a larger distance than is capable with receiver coil 108. This arrangement may have a much greater range than that achieved by using receiver coil 108 because the detection coils may be optimized for detection of the magnetic field strength rather than for receipt of wirelessly transmitted power. In some embodiments, a separate antenna can be used to detect a beacon that is placed in the vicinity of transmit coil 106. In some cases, the beacon can be placed at the center of transmit coil 106 and can be used to fully align device 110 with transmitter 102. In some cases, device 110 can switch from detecting the beacon to alignment using the magnetic field of transmit coil 106 as described above when the magnetic field becomes strong enough.

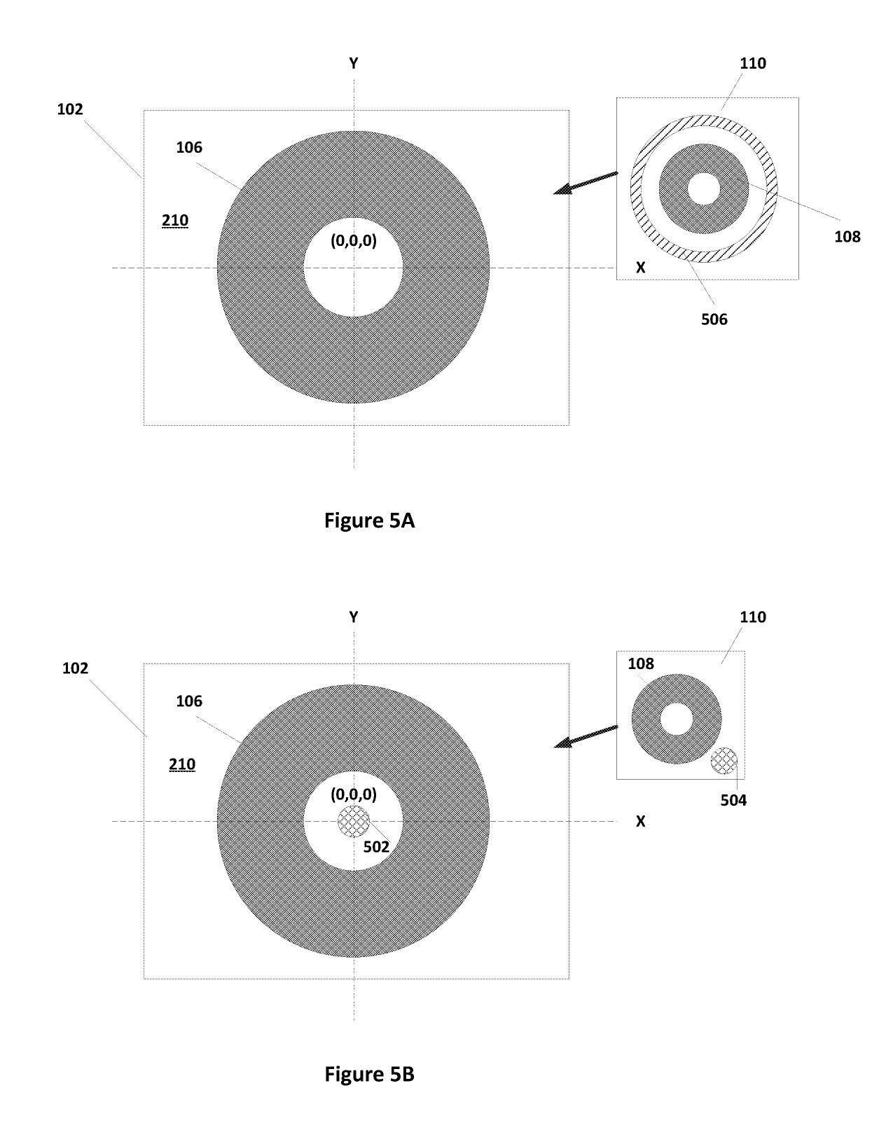

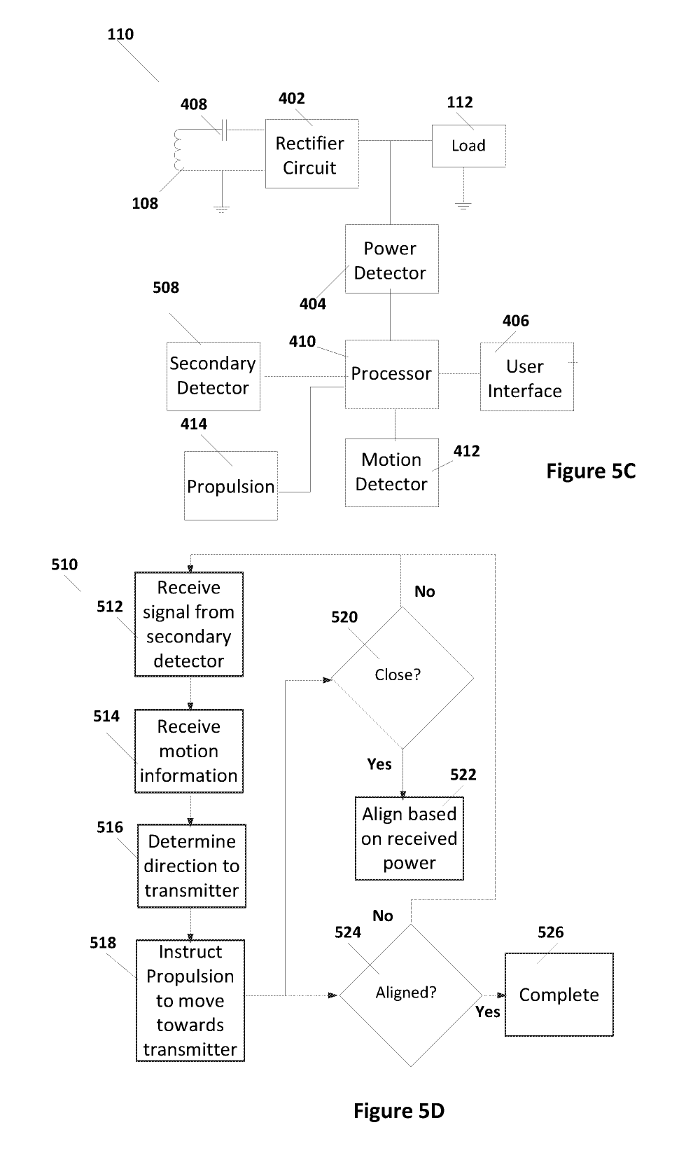

FIG. 5A illustrates an embodiment where a separate antenna 506 is provided on device 110 that allows for detection of the magnetic field from transmit coil 106 from a larger distance than is possible using receive coil 108 itself. Although in FIG. 5A separate antenna 506 is shown as being concentric with receive coil 108, in some embodiments antenna 506 can be placed anywhere on device 110. In some embodiments, as soon as detection of the magnetic field with receiver coil 108 becomes strong enough, alignment can be accomplished using receiver coil 108 instead.

FIG. 5B illustrates a system where a beacon 502 is placed on transmitter pad 210 and a beacon detector 504 is provided on receiver device 110. In FIG. 5A, beacon 502 is illustrated in the center of transmit coil 106. However, beacon 502 can be placed anywhere on transmitter pad 210 where there is a magnetic field gradient from transmitter coil 106. Beacon 502 can be any device that transmits a signal to beacon detector 504 over a sufficient range. In some cases, beacon 502 may operate at a frequency or provide other characteristics that uniquely identify transmitter coil 106. In FIG. 5B, beacon detector 504 is shown adjacent to receiver coil 108. In some embodiments, beacon detector 504 may be placed concentric with receiver coil 108. In some cases, beacon 502 and beacon detector 504 can be used to completely align receive coil 108 with transmit coil 106. However, in some embodiments, device 110 uses beacon 502 until a sufficiently strong magnetic field is detected by receive coil 108 to allow for alignment using the magnetic field from transmit coil 106 as described above.

FIG. 5C illustrates an embodiment of receiver device 110 that includes a secondary detector 508. As illustrated, secondary detector 508 provides data to processor unit 410. In some embodiments, secondary detector 508 is a sensitive coil such as coil 506 that can detect the magnetic field from a larger distance than can receive coil 108. In some embodiments, secondary detector 508 can be a beacon receiver 504 that can detect a beacon signal from beacon 502. In some cases, secondary detection can be a radio receiver, for example a Bluetooth receiver, to receive a radio signal transmitted by transmitter 102.

As discussed above, in the event that secondary detector 508 is a beacon receiver 504, a similar processing to determine direction towards higher beacon signal strength can be used in detector device 110 so that receiver device 110 can locate transmitter pad 210. In some embodiments, once arriving at transmitter pad 210, processing unit 410 may use data from power detector 404 in order to position receiver device 110 optimally with respect to transmitter coil 106, or may continue to align device 110 using data from secondary detector 508. As discussed above, secondary detector 508 may be a beacon detector 504 that detects a signal from a corresponding beacon 502 or may be a separate coil 506 that is more sensitive than coil 108 in detecting the magnetic field generated from transmit coil 106 at a greater distance.

In some embodiments, there may be more than one transmitter 106 in a given area (and potentially more than one transmitter coil 106 in a single pad 210). As discussed above, receiver device 110 may navigate to a particular beacon 502 or particular transmit coil 106. Unique properties of a beacon 502 or the magnetic field generated by transmit coil 106 can allow secondary detector 508 to locate a particular transmit coil 106.

In some embodiments where secondary detector 508 is a beacon 504, beacon 502 may have an on-off signature pattern that is unique for that beacon. Processor 410 of receiver device 110 may recognize the pattern of the desired beacon, which would be stored in memory in processor unit 410. By having significant “off” time and by having differences among the beacons from various ones of transmit coils 106 as to the repetition rate, durations, and other characteristics, then receiver device 110 can find the desired transmitter beacon 502 associated with transmitter coil 106, even when multiple transmitter beacons are present in the area.

As discussed above, another way to distinguish between multiple transmitter beacons is by providing each beacon 502 with a signature frequency and/or amplitude variation that the transmitter can make during a predetermined “on” time. When beacon 502 detects a nearby potential receiver device 110, it can switch to a continuous-on mode which can make it easier for receiver device 110 to navigate to the optimum location.

In some embodiments, transmitter beacon 502 may “listen” for other nearby transmitter beacons. If none are nearby, then transmitter beacon 502 may go to a continuous mode or similar that would make it easier for receiver device 110 to follow the beacon signal. Or, if transmitter beacon 502 does detect other nearby transmitter beacons, then implicitly coordinated activities with other beacons may also make it easier for the Receiver to follow the desired signal.

In some embodiments, beacon 502 may be audio (ultrasound) or a radio beacon. In some embodiments, transmitter 102 and receiver device 110 may be in radio contact. Radio contact may provide for handshaking between transmitter 102 and receiver device 110, which may be used to help device 110 verify the correct transmitter 102. In some embodiments, a radio link may be used to modify beacon 502 in order to better enable receiver device 110 to navigate to its location.

Similar techniques can be used where secondary detector 508 is a coil for measuring the magnetic field from transmission coil 106. In some cases, if there are multiple transmission coils, each transmission coil 106 may operate at a different frequency or the frequency of the magnetic field transmitted from transmission coil 106 may be modulated in a unique fashion. In either case, coil 506 detects the magnetic field from transmission coil 106 and processor 410 can recognize the particular modulation or frequency of the magnetic field in order to direct device 110 to that particular one of transmission coil 106.

FIG. 5D illustrates an algorithm 510 that may be executed by processor 410 when a secondary detector 508 is used. As illustrated in algorithm 510, processor 410 can receive a signal from the second detector 508 in step 512 and receive motion information from motion detector 412 in step 514. In step 516, processor 410 determines a direction towards transmitter 102. The directional calculation can be made by measuring a gradient of the signal strength, either from a beacon 502 or from transmission coil 106.

In step 518, propulsion 414 is directed to move in the direction towards transmitter 102 that is determined in step 516. In some embodiments, algorithm 510 proceeds to step 524, where it is determined whether alignment has been achieved using the secondary detector 508. If so, then algorithm 510 proceeds to step 526 where algorithm 510 indicates completion and stops. If not, then algorithm returns to step 512.

In other embodiments, algorithm 510 proceeds from step 518 to step 520, where it is determined whether device 110 is close enough to transmitter 102 to allow for alignment using receive coil 108. If device 110 is close enough, then algorithm 510 proceeds to step 522 where alignment is accomplished by algorithm 424 illustrated in FIG. 4C. If not, then algorithm 510 returns to step 512.

Guidance of receiver device 110 by various cues or by information provided to a robotic operator can therefore be provided by feedback signals in receive device 110 to perform precise placement of receive device 110 with respect to transmitter coil 106. Systems according to some embodiments may be suitable for a wide range of wireless power products where there is otherwise a large uncertainty in physical placement of receive devices with respect to transmitter coil 106. One area of importance is robotically placing a receive device such as by quadcopter where cost of alternative guidance methods is undesirable or more costly, and placement of receive device 110 on transmit coil 106 otherwise has a very large uncertainty in physical accuracy.

The above detailed description is provided to illustrate specific embodiments of the present invention and is not intended to be limiting. Numerous variations and modifications within the scope of the present invention are possible. The present invention is set forth in the following claims.

What is claimed is:

1. A wireless power receiver, comprising:
a receiver coil;
a power detector configured to determine a magnetic field strength;
a processor coupled to receive the power level from the power detector and configured to provide an indication of the power level, wherein an alignment between the receiver coil and a corresponding transmitter coil can be accomplished based at least in part on the power level.

2. The receiver of claim 1, further including:
a user interface that includes a power level meter coupled to receive the power level from the processor wherein a user can move the wireless power receiver according to the power level indicated on the power level meter to achieve alignment.

3. The receiver of claim 1, further including a motion detector coupled to the processor, wherein the processor is configured to determine a direction to move the power receiver based on a gradient of the power level received with position.

4. The receiver of claim 3, further including a user interface coupled to the processor wherein the processor is configured to indicate the direction on the user interface.

5. The receiver of claim 3, further including a propulsion device coupled to the processor, wherein the processor is configured to provide control signals to the propulsion device that moves the receiver in the direction.

6. The receiver of claim 1, further including a secondary detector coupled to the processor, the secondary detector providing signals from the transmitter that includes the corresponding transmitter coil, wherein the processor is configured to provide the direction to alignment based on signals from the secondary detector.

7. The receiver of claim 6, wherein the secondary detector is a beacon detector to receive a beacon signal from a beacon on the transmitter.

8. The receiver of claim 7, wherein the beacon signal from the beacon uniquely identifies a particular transmitter coil on the transmitter.

7. The receiver of claim 6, wherein the secondary detector is a radio receiver in radio communications with the transmitter.

8. A method of aligning a receiver with a transmitter, comprising:
receiving a power signal indicating a received wireless power from the transmitter; and
determining an alignment of the receiver with the transmitter based on the power signal.

9. The method of claim 8, further including
receiving a motion information signal;
determining power gradients from the power signal and the motion information signal; and
determining a direction towards the alignment.

10. The method of claim 9, further including providing instructions to a propulsion system to move in the direction towards the alignment.

11. A method of aligning a receiver with a transmitter, comprising:
receiving a secondary signal from a secondary detector; and
determining a direction towards alignment based from the secondary signal.

12. The method of claim 11, wherein the secondary detector is a beacon detector.

13. The method of claim 11, wherein the secondary detector is a coil detecting a magnetic field from the transmitter.

14. The method of claim 11, wherein the secondary detector is a radio receiver.

15. The method of claim 11, further including
performing an alignment based on a power signal indicating wireless power received from the transmitter when the receiver is close enough to the receiver to detect the power signal.

16. The method of claim 15, wherein performing an alignment based on a power signal includes:
receiving the power signal;
receiving a motion information;
determining a power gradient from the power signal and the motion information; and
determining a direction towards alignment from the power gradient.
